(19) United States
(12) Patent Application Publication
(10) Pub. No.: US 2019/0025358 A1
(43) Pub. Date: Jan. 24, 2019

(54) MEASURING SYSTEM WITH POSITIONING SYSTEM FOR BEAMFORMING MEASUREMENTS AND MEASURING METHOD

(71) Applicant: Rohde & Schwarz GmbH & Co. KG, Munich (DE)

(72) Inventors: Corbett ROWELL, Munich (DE); Vincent ABADIE, Hohenschaeftlarn (DE)

(21) Appl. No.: 15/713,018

(22) Filed: Sep. 22, 2017

(30) Foreign Application Priority Data
Jul. 21, 2017 (EP) 17182531.8
Sep. 6, 2017 (EP) 17189575.8

(51) Int. Cl. G01R 29/10; H01Q 1/12; H01Q 3/44

(52) U.S. Cl. CPC G01R 29/105; H01Q 3/12; H01Q 3/446; H01Q 1/1257

(57) ABSTRACT

A measuring system comprising a measuring antenna, a link antenna and a positioning system is provided. The measuring antenna is configured to perform over the air measurements on a device under test. The link antenna is configured to perform communications with the device under test. The positioning system comprises a first rotational positioner, configured to rotate the device under test around a first axis. The positioning system further comprises a second rotational positioner, configured to rotate the measuring antenna around a second axis. The first rotational positioner is connected to the link antenna, and is thereby configured to rotate the link antenna around the device under test around the first axis.

### RELATED APPLICATION(S)

The present application claims priority from European Patent Application Nos. EP17182531.8 (filed 2017 Jul. 21) and EP17189575.8 (filed 2017 Sep. 6), the entireties of which are incorporated herein by reference.

### TECHNICAL FIELD

The present invention relates to measuring the accuracy of a device under test performing beamforming, and more specifically the invention encompasses a measuring system and a measuring method for this purpose.

### BACKGROUND

In order to perform accurate measurements, such as determining if a device under test correctly performs beamforming, over the air measurements are necessary. This means that a link antenna is in communications with the device under test and instructs the device under test to adopt specific beamforming parameters. A separate measuring antenna determines a transmission pattern around the device under test. In an ideal set up, the device under test, the link antenna and the measuring antenna can be positioned or oriented freely. In practice, this would be very complicated and would require a very complex measurement setup.

The U.S. Pat. No. 8,823,593 B2 shows a measuring system and method in which the device under test is arranged on a turntable and can thus only be turned around a single axis. Moreover, a measuring antenna is mounted rotatably around a perpendicular plane with regard to the rotation of the device under test. It is thereby possible to measure all positions around the device under test. The system and method shown there though is disadvantageous in that the use of a link antenna is not employed in the disclosed measuring system and method.

What is needed, therefore, is an approach for a measuring system and a measuring method, which allow over the air measurements on a device under test for checking the beamforming compliance of the device under test.

### SOME EXAMPLE EMBODIMENTS

Embodiments of the present invention advantageously address the foregoing requirements and needs, as well as others, by providing a measuring system and a measuring method that facilitate over the air measurements on a device under test for checking the beamforming compliance of the device under test.

According to a first aspect of the invention a measuring system comprising a measuring antenna, a link antenna and a positioning system is provided. The measuring antenna is configured to perform over the air measurements on a device under test. The link antenna is configured to perform communications with the device under test. The positioning system comprises a first rotational positioner configured to rotate the device under test at least around a first axis. The positioning system further comprises a second rotational positioner configured to rotate the measuring antenna at least around a second axis. The first rotational positioner is connected to the link antenna, and thereby configured to rotate the link antenna around the device under test around the first axis. It is thereby possible to measure a great plurality of different measuring positions and thereby check the beamforming compliance of then device under test.

According to a first implementation form of the first aspect, the first rotational positioner is configured to rotate the link antenna together with the device under test around a position of the device under test, while maintaining an alignment of the device under test with regard to the link antenna. This allows for a very simple construction of the system.

According to a further implementation form of the first aspect, the first rotational positioner is configured to rotate the link antenna within a coordinate system of the device under test. This simplifies ensuing calculations significantly.

According to a further implementation form of the first aspect, the positioning system further comprises a third rotational positioner configured to rotate the device under test around a third axis. This allows for positioning the link antenna at different angles with regard to the device under test by rotating the device under test with regard to the link antenna. Thereby, further degrees of freedom while performing the beamforming compliance tests are provided.

According to a further implementation form of the first aspect, the third rotational positioner is configured to not rotate the link antenna around the third axis. The alignment between the device under test and the link antenna is thereby changed while rotating the device under test around the third axis.

According to a further implementation form of the first aspect, the positioning system is configured to position the device under test within a spherical coordinate system. Thereby a great flexibility for performing the tests is given.

According to a further implementation form of the first aspect, the measuring system comprises an anechoic chamber within which the measuring antenna, the link antenna and the positioning system are arranged. This reduces outside interference on the measurement.

According to a further implementation form of the first aspect, the measuring system comprises a measuring device connected to the measuring antenna. The measuring device is configured to measure first measuring signals emitted by the device under test and received by the measuring antenna. Additionally or alternatively, the measuring device is configured to generate second measuring signals. In this case, the measuring antenna emits the second measuring signals towards the device under test. It is thereby possible to perform measurements in both measuring directions.

According to a further implementation form of the first aspect, the measuring system comprises a link controller configured to perform communications with the device under test via the link antenna. Great flexibility with regard to the signaling between the device under test and the link antenna is thereby achieved.

According to a further implementation form of the first aspect, the link controller is configured to generate link control signals and to transmit the link control signals to the device under test via the link antenna, wherein the link control signals instruct the device under test to adjust at least one communication parameter. It is thereby possible to influence the device under test to switch between different operating modes, such as different beamforming patterns.

According to a further implementation form of the first aspect, the at least one communication parameter is one or more of a beamforming parameter, a MIMO parameter and a transmission parameter. Thereby, great flexibility with regard to adjusting the settings of the device under test is achieved.

According to a further implementation form of the first aspect, the positioning system comprises a fourth rotational positioner configured to rotate the link antenna around a fourth axis. Additionally or alternatively, the positioning system comprises a longitudinal positioner configured to move the link antenna longitudinally. Thereby, additional degrees of freedom for positioning the device under test with regard to the link antenna are achieved. A higher number of different test scenarios can thereby be performed by the measuring system.

According to a further implementation form of the first aspect, the positioning system comprises a fifth rotational positioner configured to rotate the device under test around the first axis relative to the link antenna. This allows for an even greater flexibility of positioning of the link antenna.

According to a second aspect of the invention, a method for performing measurements on a device under test is provided. The method comprises instructing the device under test to adopt a beamforming using a link antenna, to position the device under test, using a first rotational positioner, to direct a beamforming beam towards the link antenna, and to perform a measurement using a measuring antenna. It is thereby possible to determine measurements with minimal effort.

According to a first implementation form of the second aspect, the method further comprises, after the step of performing a measurement, successively positioning the measuring antenna at a further measuring position, using a second rotational positioner, and performing measurements until measurements at a plurality of desired measurement positions have been performed. It is thereby possible to perform 3D measurements using only two different rotational positioners.

According to a further implementation form of the second aspect, the method further comprises determining a 3D radiation pattern from the plurality of measurements. A very simple determining of measurement results is thereby possible.

According to a further implementation form of the second aspect, the method further comprises, after the step of positioning the device under test to direct the beamforming beam towards the link antenna, positioning the device under test, using a third rotational positioner, to direct the beamforming beam towards the link antenna. It is thereby possible to three dimensionally align the device under test with regard to the link antenna and thereby determine three dimensional beamforming measurements.

Still other aspects, features, and advantages of the present invention are readily apparent from the following detailed description, simply by illustrating a number of particular embodiments and implementations, including the best mode contemplated for carrying out the present invention. The present invention is also capable of other and different embodiments, and its several details can be modified in various obvious respects, all without departing from the spirit and scope of the present invention. Accordingly, the drawing and description are to be regarded as illustrative in nature, and not as restrictive.

### BRIEF DESCRIPTION OF THE DRAWINGS

Embodiments of the present invention are illustrated by way of example, and not by way of limitation, in the figures of the accompanying drawings, in which like reference numerals refer to similar elements, and in which:

FIG. 1 shows a first example of a measuring system, in accordance with example embodiments of the present invention;

FIG. 2 shows a second example of a measuring system, in accordance with example embodiments of the present invention; and

FIG. 3 shows an example of a measuring method, in accordance with example embodiments of the present invention.

### DETAILED DESCRIPTION

A measuring system and a measuring method, which facilitate over the air measurements on a device under test for checking the beamforming compliance of the device under test, are described. In the following description, for the purposes of explanation, numerous specific details are set forth in order to provide a thorough understanding of the invention. It is apparent, however, that the invention may be practiced without these specific details or with an equivalent arrangement. In other instances, well-known structures and devices are shown in block diagram form in order to avoid unnecessarily obscuring the invention.

As will be appreciated, a processor, unit, module or component (as referred to herein) may be composed of software component(s), which are stored in a memory or other computer-readable storage medium, and executed by one or more processors or CPUs of the respective devices. As will also be appreciated, however, a module or unit may alternatively be composed of hardware component(s) or firmware component(s), or a combination of hardware, firmware and/or software components. Further, with respect to the various example embodiments described herein, while certain of the functions are described as being performed by certain components or modules (or combinations thereof), such descriptions are provided as examples and are thus not intended to be limiting. Accordingly, any such functions may be envisioned as being performed by other components or modules (or combinations thereof), without departing from the spirit and general scope of the present invention. Moreover, the methods, processes and approaches described herein may be processor-implemented using processing circuitry that may comprise one or more microprocessors, application specific integrated circuits (ASICs), field programmable gate arrays (FPGAs), or other devices operable to be configured or programmed to implement the systems and/or methods described herein. For implementation on such devices that are operable to execute software instructions, the flow diagrams and methods described herein may be implemented in processor instructions stored in a computer-readable medium, such as executable software stored in a computer memory store.

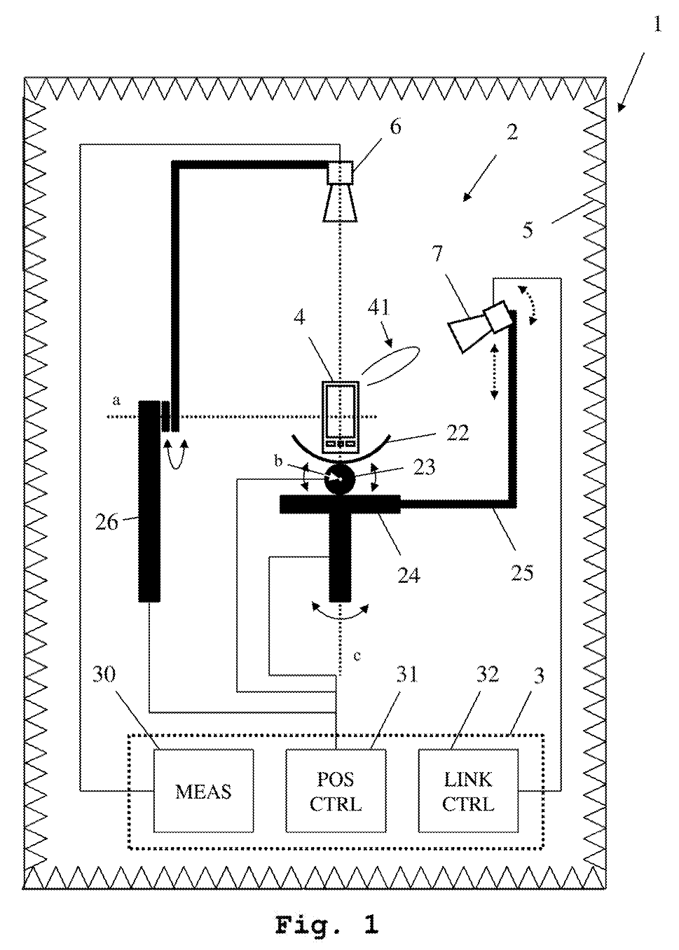

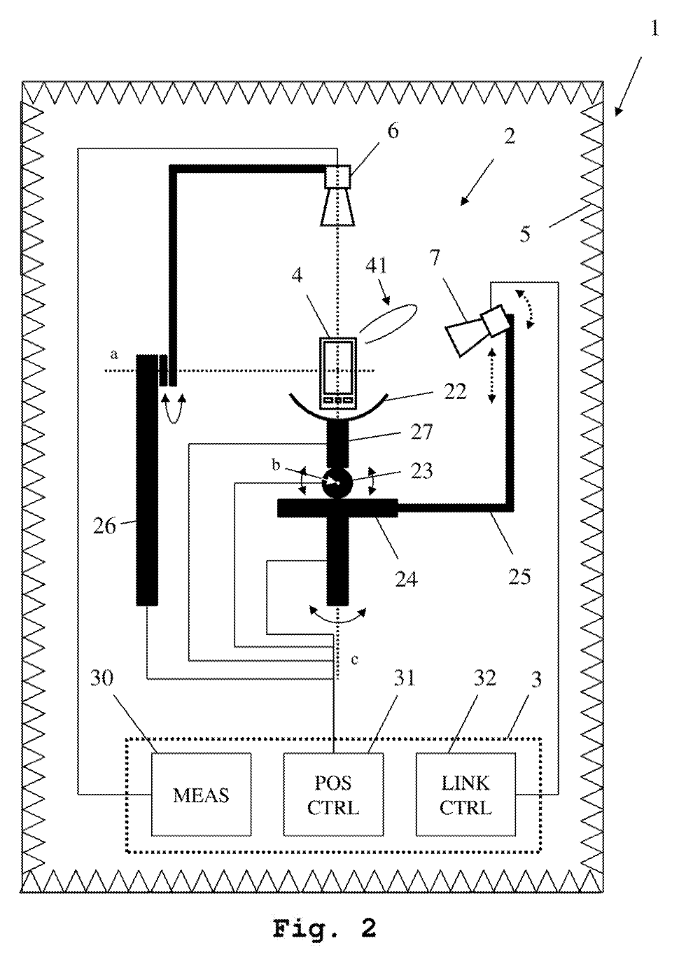

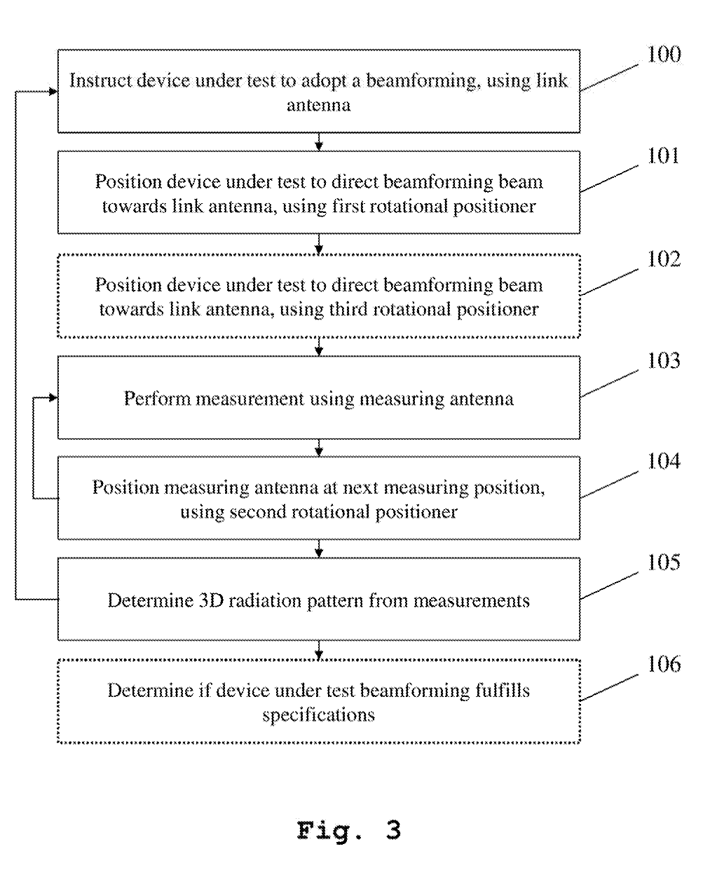

The construction and function of example measuring systems, according to example embodiments, are described with reference to FIG. 1 and FIG. 2. The function of an example measuring method, according to example embodiments, is then described with reference to FIG. 3. Similar entities and reference numbers and different figures have been partially omitted. Further, the positioner elements described herein may also be referred to as mounts.

FIG. 1 shows a first example of a measuring system 1, in accordance with example embodiments of the present invention. The measuring system 1 comprises a positioning system 2, which positions a device under test 4. The measuring system 1 further comprises a processing unit 3. The measuring system in addition comprises a measuring antenna 6 and a link antenna 7. The measuring antenna 6 and the link antenna 7 are also positioned by the positioning system 2.

The measuring system 1 may further comprise an anechoic chamber 5, within which the positioning system 2, the processing unit 3, the device under test 4, the measuring antenna 6 and the link antenna 7 are arranged. Alternatively, the processing unit 3 can be arranged outside of the anechoic chamber. It is important to note though, that the anechoic chamber 5 is an optional component.

The device under test 4 is held by a device under test holder 22. The device under test holder 22 mechanically connects the device under test 4 to a rotational positioner 23, which is adapted to rotate the device under test 4 with the device under test holder 22 around an axis b. The rotational positioner 23 is arranged on a turntable 24, which constitutes a further rotational positioner 24. The rotational positioner 24 is adapted to rotate the device under test 4, the device under test holder 22 and the rotational positioner 23 around an axis c. Connected to the turntable is an arm 25 holding the link antenna 7. The link antenna 7 is thereby rotatable with the turntable around the axis c and thereby around the device under test 4. As long as the rotational positioner 23 does not perform any rotation, the device under test 4 and the link antenna 7 stay aligned to each other, without changing their angle with regard to each other, since the arm 25 fixedly connects the link antenna 7 to the turntable 24, even when the rotational positioner 24 rotates the device under test 4 and the device under test holder 22.

Alternatively or additionally, the link antenna 7 may optionally be connected to the arm 25 by use of a further rotational positioner and/or by use of a longitudinal positioner. Thereby, the position and/or alignment of the link antenna 7 with regard to the device under test 4 can be adapted.

The measuring antenna 6 is held in place by a further rotational positioner 26, which is adapted to rotate the measuring antenna 6 around an axis a. It is thereby possible to position the measuring antenna 6 around a 360° arc around the device under test 4. By use of the rotational positioners 23, 24 and 26, it is thereby possible to arrange the measuring antenna 6 in any direction with regard to the device under test 4.

The processing unit 3 comprises a measuring device 30, which is connected to the measuring antenna 6. In a first measuring direction, the measuring device 30 receives a first measuring signal emitted by the device under test, received via the measuring antenna 6. In a second measuring direction, the measuring device 30 generates a second measuring signal and emits it towards the device under test 4 via the measuring antenna 6. It is thereby possible to determine a three dimensional radiation pattern of signals emitted by the device under test, and also of signal received by the device under test. Therefore, a transmission beamforming as well as reception beamforming can be tested.

Further, the processing unit 3 comprises a position controller 31, which is connected to the positioners 23, 24, 26. The position controller 31 controls the operation of the positioners 23, 24 and 26. In case of the link antenna 7 being connected to the arm 25 by a further positioner, this further positioner is also connected to the position controller 31 and controlled thereby.

The processing unit 3 further comprises a link controller 32, which is connected to the link antenna 7. The link controller 32 controls the communication between the device under test 4 and the link antenna 7, and receives and generates respective signals. By way of example, the link controller 32 generates a link signal and transmits it to the device under test 4 by use of the link antenna 7, in order to instruct the device under test 4 to adopt a specific communication parameter, for example a beamforming parameter or a MIMO parameter or any other form of communication parameter.

The use of the anechoic chamber 5 ensures that no stray emissions from outside influence the measurements.

In FIG. 1, a beam 41 of a signal emitted by the device under test 4 is shown. This beam can for example be achieved by beamforming.

FIG. 2 shows a second example of the measuring system 1, in accordance with example embodiments of the present invention. Here, the positioning system 2 comprises an additional rotational positioner 27, which is arranged between the device under test holder 22 and the rotational positioner 23, and mechanically connects the device under test holder 22 and the rotational positioner 23. The rotational positioner 27 is adapted to rotate the device under test 4 together with the device under test holder 22 around the axis c. This rotation is independent of the rotation by the rotational positioner 24, which rotates the device under test holder 22, the rotational positioner 27, and the rotational positioner 23.

By use of the rotational positioner 24, it is thereby possible to rotate the device under test 4 together with the link antenna 7, without changing the alignment of the device under test 4 with regard to the link antenna 7.

By use of the rotational positioner 27, it is further possible to rotate the device under test 4 with regard to the link antenna 7 as well as with regard to the measuring antenna 6.

FIG. 3 shows an example of a measuring method, in accordance with example embodiments of the present invention. In step 100, a device under test is instructed to adopt a specific beamforming, using a link antenna. In step 101, the device under test is positioned to direct the beamforming beam towards the link antenna using a first rotational positioner. Optionally, if there are more positioners, such as rotational positioners available covering more degrees of freedom, they can also be used to further position the device under test with regard to the link antenna.

In an optional step 102, the device under test is further positioned to direct the beamforming beam towards the link antenna using a third rotational positioner. Employment of this step facilitates a three dimensional positioning with regard to the link antenna. Optionally, if there are more positioners, such as rotational positioners available covering more degrees of freedom, they can also be used to further position the device under test with regard to the measuring antenna.

In step 103, a measurement is performed using a measuring antenna. In step 104, the measuring antenna is positioned at a next measuring position using a second rotational positioner. After this step, the steps 103 and 104 are repeated, until all measuring positions with regard to the present beamforming setup are measured. In step 105, a three dimensional radiation pattern is determined from these measurements. The steps 100-105 may then be repeated for a number of different beamforming settings. In an optional step 107, it is determined if the device under test satisfies applicable beamforming specifications, for example, by comparing the determined 3D radiation patterns with a look-up table.

The invention is not limited to the examples and especially not to specific types of devices under test. The characteristics of the exemplary embodiments can be used in any advantageous combination.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

What is claimed is:

1. A measuring system comprising a measuring antenna, a link antenna, and a positioning system, wherein the measuring antenna is configured to perform over the air measurements on a device under test, wherein the link antenna is configured to perform communications with the device under test, and wherein the positioning system comprises:
a first rotational mount configured to rotate the device under test around at least a first axis; and
a second rotational mount configured to rotate the measuring antenna around at least a second axis; and
wherein the first rotational mount is connected to the link antenna and is configured to rotate the link antenna around the device under test, around the first axis.

2. The measuring system according to claim 1, wherein the first rotational mount is configured to rotate the link antenna together with the device under test around a position of the device under test, and to thereby maintain an alignment of the device under test with regard to the link antenna.

3. The measuring system according to claim 1, wherein the first rotational mount is configured to rotate the link antenna within a coordinate system of the device under test.

4. The measuring system according to claim 1, wherein the positioning system further comprises a third rotational mount configured to rotate the device under test around a third axis.

5. The measuring system according to claim 4, wherein the third rotational mount is configured to change an alignment between the device under test and the link antenna while rotating the device under test around the third axis.

6. The measuring system according to claim 4, wherein the positioning system is configured to position the device under test within a spherical coordinate system.

7. The measuring system according to claim 1, further comprising an anechoic chamber, wherein the measuring antenna, the link antenna, and the positioning system are arranged within the anechoic chamber.

8. The measuring system according to claim 1, further comprising a measuring device connected to the measuring antenna, wherein the measuring device is configured to one or more of measure first measuring signals emitted by the device under test and received by the measuring antenna, and generate second measuring signals, wherein the measuring antenna is configured to emit the second measuring signals towards the device under test.

9. The measuring system according to claim 1, further comprising a link controller configured to perform communications with the device under test via the link antenna.

10. The measuring system according to claim 9, wherein the link controller is configured to generate link control signals and to transmit the link control signals to the device under test via the link antenna, wherein the link control signals instruct the device under test to adjust at least one communication parameter.

11. The measuring system according to claim 10, wherein the at least one communication parameter comprises one or more of a beamforming parameter, a MIMO parameter and a transmission pattern.

12. The measuring system according to claim 1, wherein the positioning system further comprises one or more of a fourth rotational mount configured to rotate the link antenna around a fourth axis, and a longitudinal mount configured to move the link antenna longitudinally.

13. The measuring system according to claim 1, wherein the positioning system further comprises a fifth rotational mount configured to rotate the device under test around the first axis relative to the link antenna.

14. A method for performing measurements of a device under test, comprising:
instructing the device under test to adopt a beamforming, using a link antenna;
positioning the device under test to direct a beam of the beamforming towards the link antenna, using a first rotational mount; and
performing a measurement, using a measuring antenna.

15. The method according to claim 14, further comprising:
after the step of performing a measurement, successively positioning the measuring antenna at a next measuring position, using a second rotational mount; and
performing a plurality of measurements at a plurality of respective measurement positions.

16. The method according to claim 15, further comprising:
determining a three dimensional radiation pattern from the plurality of measurements.

17. Method according to claim 14, further comprising:
after the step of positioning the device under test to direct the beamforming beam towards the link antenna, using the first rotational mount, positioning the device under test to direct the beamforming beam towards the link antenna using a third rotational mount.
